(19) United States
(12) Patent Application Publication
(10) Pub. No.: US 2003/0114018 A1
(43) Pub. Date: Jun. 19, 2003

(54) Method for fabricating a semiconductor component

(76) Inventors: Martin Gutsche, Dorfen (DE); Thomas Hecht, Dresden (DE); Stefan Jakschik, Dresden (DE); Matthias Leonhardt, Stuttgart (DE); Hans Reisinger, Grunwald (DE); Uwe Schroeder, Dresden (DE); Kristin Schupke, Weixdorf (DE); Harald Seidl, Feldkirchen (DE)

Correspondence Address: JENKINS & WILSON, PA, 3100 TOWER BLVD, SUITE 1400, DURHAM, NC, 27707, US

(21) Appl. No.: 10/180,808

(22) Filed: Jun. 26, 2002

(30) Foreign Application Priority Data
Jun. 27, 2001 (DE) 101 30 936.8

(51) Int. Cl. H01L 21/31

(52) U.S. Cl. 438/788

(57) ABSTRACT

The present invention provides a method for fabricating a semiconductor component having a substrate (1) and a dielectric layer (70) provided on or in the substrate (1), the dielectric layer (7) being deposited in alternating self-limiting monolayer form, in the form of at least two different precursors, by means of an ALD process. There is provision for conditioning of the surface of the substrate (1) prior to the deposition of a first monolayer of a first precursor with respect to a reactive ligand of the first precursor.

The present invention relates to a method for fabricating a semiconductor component having a substrate and a dielectric layer provided on or in the substrate, the dielectric layer being deposited in alternating self-limiting monolayer form, in the form of at least two different precursors, by means of an ALD process.

The term substrate is to be understood in a general sense and may therefore comprise both single-layer and multilayer substrates.

Although it can be applied to any desired semiconductor components, the present invention and the problem on which it is based are explained with respect to capacitors used in silicon technology.

What are known as single-transistor cells are used in dynamic random access memories (DRAMs). These cells comprise a storage capacitor and a select transistor which connects the storage electrode to the bit line. The storage capacitor may be formed as a trench capacitor or as a stacked capacitor. The invention described here relates in very general terms to capacitors for such DRAMs in the form of trench capacitors and stacked capacitors.

It is known to fabricate a capacitor of this type, for example for a DRAM (Dynamic Random Access Memory) having the electrode layer—insulator layer—electrode layer structure, it being possible for the electrode layers to be metal layers or (poly)silicon layers.

To further increase the storage density for future technology generations, the feature size is being reduced from generation to generation. The increasingly small capacitor area and the resulting reduction in the capacitance of the capacitor leads to problems. It is therefore important to keep the capacitor capacitance at least constant despite the reduction in feature size. This can be achieved, inter alia, by increasing the charge density per unit area of the storage capacitor.

Hitherto, this problem has been solved firstly by increasing the available capacitor area (for a predetermined feature size) . This can be achieved, for example, by the deposition of polysilicon with a rough surface (hemispherical silicon grains) in the trench or on the lower electrode of the stacked capacitor. Secondly, hitherto the charge density per unit area has been increased by reducing the thickness of the dielectric. Hitherto, only various combinations of SiO₂ (silicon oxide) and Si₃N₄ (silicon nitride) have been used as dielectric for DRAM capacitors.

Furthermore, a few materials with a higher dielectric constant have been proposed for stacked capacitors. These specifically include Ta₂O₅ and BST (Barium Strontium Titanate). However, these materials are chemically unstable at elevated temperatures in direct contact with silicon or polysilicon. Moreover, the materials themselves have only an inadequate temperature stability. A further possibility is to nitride the lower electrode of the capacitor then to deposit a CVD silicon nitride, which is then reoxidized in a wet oxidation step. Because of the increased leakage currents which result, a further reduction in the thickness of these dielectrics is not possible.

Recently, further materials with a higher dielectric constant have been proposed, e.g. Al₂O₃, ZrO₂, HFO₂, and the like, which can be deposited in self-limiting monolayer form using the ALD (Atomic Layer Deposition) process. Particularly in the case of structures with very high aspect ratios, these new materials can be deposited with very good edge coverage and can therefore be combined excellently with methods aimed at increasing the surface area (e.g. wet bottle, HSG).

In the ALD process, the deposition process is divided into at least two individual steps A and B corresponding to two precursors, which are carried out alternately in order to form a structure sequence ABABAB . . . , each individual step ideally leading to self-limiting deposition of a monolayer of the relevant precursor. The two precursors in this case consist of molecules which each consist of the atoms which are to be deposited and a ligand. The ligands are such that chemical bonding is in each case only possible with the previous precursor molecule but not with the identical precursor molecule (cf. for example Ofer Sneh, European Semiconductor, July 2000, page 33).

A critical step in the context of the ALD process is the deposition of the first layer directly on the substrate surface.

The object of the present invention is to provide an improved method for fabricating a semiconductor component of the type described in the introduction, in which surface conditioning takes place with a sufficient number of reactive groups which can form a chemical bond with the ligands of the first precursor molecule.

According to the invention, this object is achieved by the fabrication method described in claim 1.

The general idea on which the present invention is based consists in providing for conditioning of the surface of the substrate prior to the deposition of a first monolayer of a first precursor with respect to a reactive ligand of the first precursor.

The present invention describes in particular various methods for conditioning the substrate surface.

The subclaims give advantageous developments of and improvements to the subject matter of the invention.

According to a preferred development, for the conditioning a silicon oxide layer is removed from the surface of the substrate. A silicon oxide layer of this type would reduce the effective dielectric constant of the capacitor material.

According to a further preferred development, OH, H or H₂ conditioning of the surface of the substrate is provided. This has proven advantageous in particular in the case of trimethylaluminum in addition to H₂O precursor gas for the deposition of Al₂O₃ or in the case of metal chlorides in addition to H₂O precursor gas for the deposition of ZrO₂, HfO₂ and the like. The coverage density of the OH, H or H₂ conditioning of the surface of the substrate influences the deposition rate of the dielectric.

According to a further preferred development, the conditioning comprises the application of a free-radical generator to the surface of the substrate.

According to a further preferred development, the conditioning comprises a pulsed O₂/H₂O—H₂/H₂O plasma treatment.

According to a further preferred development, the conditioning comprises a pulsed H₂ plasma treatment.

According to a further preferred development, the conditioning comprises a pulsed NH₃ plasma treatment.

According to a further preferred development, the conditioning comprises production of a thermal nitride, oxynitride, plasma nitride or remote plasma nitride on the surface of the substrate.

According to a further preferred development, the conditioning comprises production of an oxide on the surface of the substrate, the oxide having a composition which contains a desired number of reactive groups with respect to the reactive ligand of the first precursor.

According to a further preferred development, the conditioning comprises the production of a chemical oxide on the surface of the substrate by means of one of the following processes:

flushing for 90 seconds with DHF solution (H₂O:HF=100:1), flushing for 5 minutes with HuangA or SC1 (standard clean 1) solution (H₂O₂+NH₃ in H₂O), flushing for 5 minutes in HuangB or SC2 (standard clean 2) solution (H₂O₂+HCl in H₂O);

flushing for 60 s with DHF+Caro's acid;

flushing with HF—H₂O₂ at 35° C. (50:1);

flushing with HF—H₂O₂ at 45° C. (20:1);

flushing with HF—H₂O₂ at 45° C. (50:1).

Advantages in this respect are that these are inexpensive batch processes which are distinguished by good uniformity, edge coverage and robustness. It is possible to produce a stable interface in situ immediately after removal of the native oxide.

Exemplary embodiments of the invention are illustrated in the drawings and explained in more detail in the description which follows.

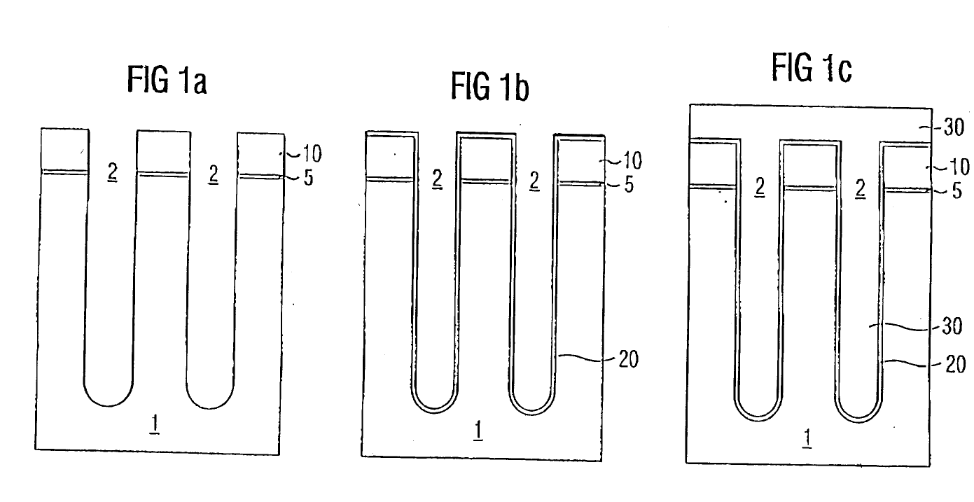

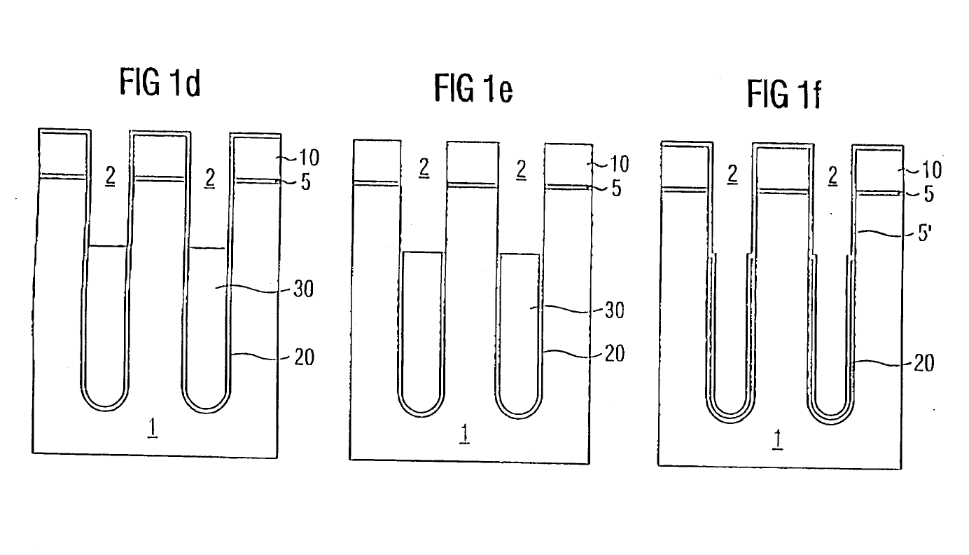

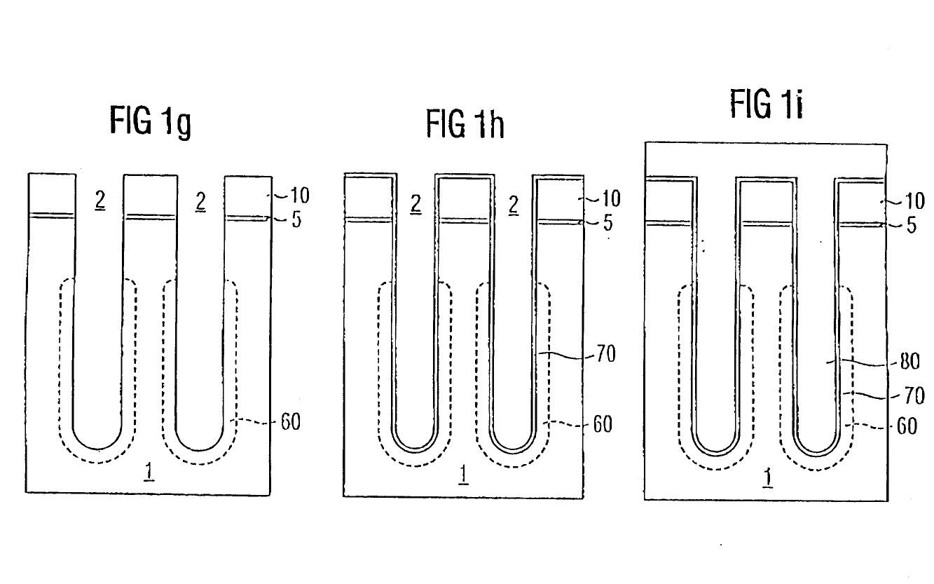

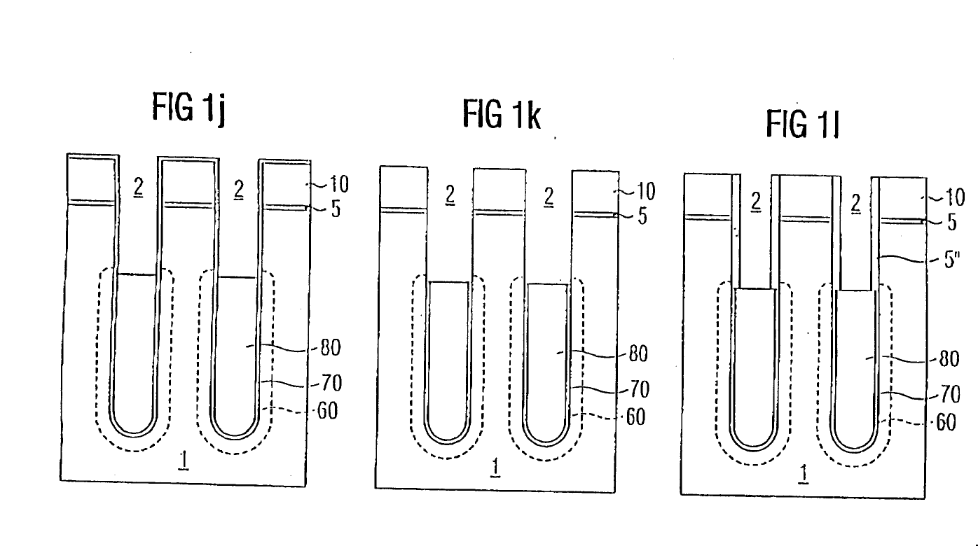

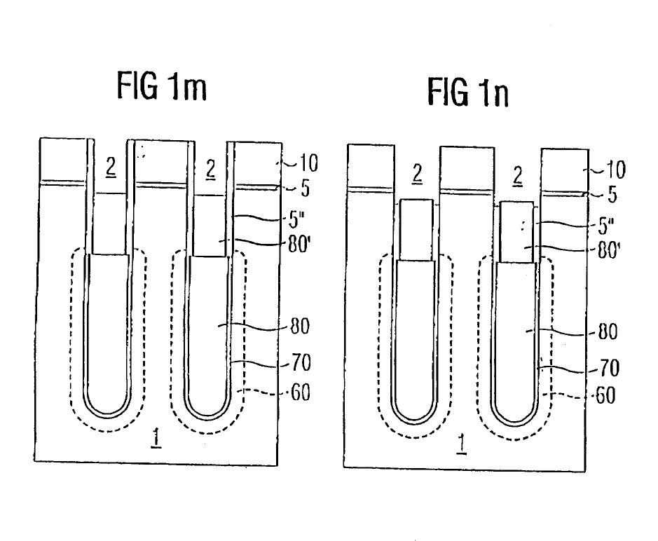

FIGS. 1a-n show the method steps for fabrication of an exemplary embodiment of the semiconductor component according to the invention, in the form of a trench capacitor, which are essential in order to gain an understanding of the invention.

In FIGS. 1a-n, identical reference numerals denote identical or functionally equivalent elements.

In the present first embodiment, first of all a pad oxide layer 5 and a pad nitride layer 10 are deposited on a silicon substrate 1, as shown in FIG. 1a. Then, a further oxide layer (not shown) is deposited, and these layers are then patterned by means of a photoresist mask (likewise not shown) and a corresponding etching process to form what is known as a hard mask. Using this hard mask, trenches 2 with a typical depth of approximately 1-10 μm are etched into the silicon substrate 1. Then, the top oxide layer is removed, in order to reach the state illustrated in FIG. 1a.

In a subsequent process step, as shown in FIG. 1b, arsenic silicate glass (ASG) 20 is deposited on the resulting structure, so that the ASG 20 in particular completely lines the trenches 2.

In a further process step, as shown in FIG. 1c, the resulting structure is filled with photoresist 30. Then, as shown in FIG. 1d, resist recessing or resist removal takes place in the upper region of the trenches 2. This is expediently carried out by isotropic dry-chemical etching.

In a further process step as shown in FIG. 1e, a likewise isotropic etch of the ASG 20 takes place in the unmasked, resist-free region, preferably using a wet-chemical etching process. Then, the resist 30 is removed in a plasma-enhanced and/or wet-chemical process.

As shown in FIG. 1f, a covering oxide 5′ is then deposited on the resulting structure.

In a further process step as shown in FIG. 1g, diffusion of the arsenic out of the remaining ASG 20 into the surrounding silicon substrate 1 takes place in a tempering step in order to form the buried plate 60, which forms a first capacitor electrode. Following this, the covering oxide 5′ and the remaining ASG 20 are removed, expediently by wet-chemical means.

Then, as shown in FIG. 1h, a special dielectric 70 with a high dielectric constant is deposited on the resulting structure, for example by means of an ALD (Atomic Layer Deposition) process, the surface of the substrate previously having been conditioned prior to the deposition of a first monolayer of a first precursor.

Three basic exemplary embodiments of a conditioning step which have a positive influence on the deposition of the first layer of the first precursor are described here.

According to a first embodiment, first of all a silicon surface, which is as far as possible free of silicon oxide, is provided on the substrate 1.

This can be achieved firstly by means of a DHF treatment (H₂O:HF=100:1) with a subsequent flush in deionized water (for example 9 minutes using 15 liters/min and 5 minutes using 5 liters/min). Alternatively, a DHF treatment with a shortened flush time can be carried out, in order, as a result of the incomplete removal of the DHF, to delay subsequent growth of the native oxide on the silicon substrate. A further possible option is plasma cleaning using NF₃, Cl₂ or the like, which can be integrated in particular in the ALD chamber, in order to avoid handling in air, with the result that subsequent growth of the native oxide on the surface of the substrate 1 is prevented once again.

A further example which may be mentioned is HF vapor cleaning in a chamber which is connected to the ALD mainframe, so that it is once again possible to avoid subsequent growth of a native oxide.

After the silicon surface which is as far as possible free of silicon oxide has been produced, the subsequent ALD deposition may take place either without further previous surface activation or with further previous surface activation.

If no further previous surface activation is used, for the abovementioned example substances trimethylaluminum in addition to H₂O precursor gas for the deposition of Al₂O₃ or metal chloride in addition to H₂O precursor gas for the deposition of ZrO₂, HfO₂, and the like, it is possible for either the precursor which contains the metal, i.e. trimethylaluminum or metal chloride, or the H₂O precursor to be deposited first. If the H₂O precursor is deposited first, an extended first H₂O pulse time is expedient, in order to increase the amount of OH groups at the surface.

If subsequent prior surface activation is desired, the following possibilities are recommended by way of example.

A first possible option is to use a pulsed O₂/H₂O—H₂/H₂O plasma, in which case in the first step the O free radicals of the oxygen bridge bonds break up, so that an O-terminated surface is formed, whereas in the second step the H free radicals react with O to form OH groups.

A further possible option is to use an H₂ plasma, in which case the H free radicals break up possible O bridges at the substrate surface. In this case, varying the chamber pressure makes it possible to control the free radical density, so that it is possible to avoid the formation of a plasma oxide.

Yet another possible option is to use an NH₃ plasma, which leads to nitriding of the surface of the substrate and to the production of an H/H₂ termination.

Finally, it is possible to use any desired free-radical generator to produce H, O or OH free radicals, in order to break up any O bridge bonds and to produce an H or OH termination.

After this surface activation, the ALD can be carried out in the usual form.

According to a second embodiment, after the removal of an oxide which may be present on the surface of the substrate 1, a nitride is produced in a first process step. This nitride may be a thermal nitride or a thermal oxynitride. In the case of the latter thermal oxynitride, the O content can be adjusted by using different NO/N₂O ratios during the treatment. A further possible option for the production of a nitride is the production of a plasma nitride or a remote plasma nitride using an RPN process.

The production of a nitride of this type has the advantage that it has a high dielectric constant and also includes suitable reactive groups for the reactive ligands of the first precursor. Therefore, in the next process step, the ALD may take place directly on the nitrided substrate 1, since the nitride surface is hydrogen-terminated.

If appropriate, as has been mentioned above in connection with the first embodiment, the deposition process may begin with a longer H₂O pulse time, in order to increase the number of OH groups at the surface.

Naturally, surface activation prior to the actual ALD may also be provided in the case of a nitrided substrate surface, as has already been described extensively above in connection with the first embodiment.

The ALD is then carried out in the customary form.

According to a third embodiment, after any native silicon oxide layer which may be present on the substrate 1 has been removed, a specific chemical oxide, which provides a sufficient number of reactive groups at the oxide surface which are able to react with the reactive ligands of the first precursor, is produced.

One example of the production of a chemical oxide of this type is the following treatment: flushing for 90 seconds with DHF solution (H₂O:HF=100:1), flushing for 5 minutes with HuangA or SC1 (standard clean 1) solution (H₂O₂+NH₃ in H₂O), flushing for five minutes in HuangB or SC2 (standard clean 2) solution (H₂O₂+HCl in H₂O). This treatment may be carried out hot or cold.

A further example is flushing for 60 s in DHF+Caro's acid.

Further examples in which it is possible to produce chemical oxides with a thickness of less than 10 Angström include the following wet-chemical processes:

a) HF—H₂O₂ at 35° C. (50:1)

b) HF—H₂O₂ at 45° C. (20:1)

c HF—H₂O₂ at 45° C. (50:1)

Then, in this case too, the ALD takes place in the customary way.

After the special dielectric 70 has been formed, in a further process step as shown in FIG. 1i arsenic-doped polycrystalline silicon 80 is deposited as second capacitor plate on the resulting structure, so that it completely fills the trenches 2. Alternatively, it would also be possible to use polysilicon-germanium or polysilicon-metal layer sequences for filling.

In a subsequent process step as shown in FIG. 1j, the doped polysilicon 80 or the polysilicon-germanium or a metal is etched back down to the upper side of the buried plate 60.

Then, to reach the state illustrated in FIG. 1k, the dielectric 70 with a high dielectric constant is etched isotropically in the upper uncovered region of the trenches 2, specifically either using a wet-chemical or a dry-chemical etching process.

In a subsequent process step as shown in FIG. 1l, a collar oxide 5′ is formed in the upper region of the trenches 2. This is achieved by depositing oxide over the entire surface and then etching the oxide anisotropically, so that the collar oxide 5′ remains in place at the side walls in the upper trench region.

As illustrated in FIG. 1m, in a subsequent process step arsenic-doped polysilicon 80′ is again deposited and etched back.

Finally, as shown in FIG. 1n, the collar oxide 5″ is removed by wet chemical means in the upper trench region.

This substantially concludes the formation of the trench capacitor. The forming of the capacitor connections and the fabrication and connection to the associated select transistor are well known in the prior art and require no further mention in connection with the explanation of the present invention.

Although the present invention has been described above with reference to a preferred exemplary embodiment, it is not restricted thereto, but rather can be modified in numerous ways.

In particular, the invention is not restricted to trench capacitors, but rather can be applied to any desired capacitors or other structures with a dielectric on a substrate.

1. Method for fabricating a semiconductor component having a substrate (1) and a dielectric layer (70) provided on or in the substrate (1), the dielectric layer (7) being deposited in alternating self-limiting monolayer form, in the form of at least two different precursors, by means of an ALD process; characterized by the step of:
providing for conditioning of the surface of the substrate (1) prior to the deposition of a first monolayer of a first precursor with respect to a reactive ligand of the first precursor.

2. Method according to claim 1, in which for the conditioning a silicon oxide layer is removed from the surface of the substrate (1).

3. Method according to claim 1 or 2, in which OH, H or H₂ conditioning of the surface of the substrate (1) is provided.

4. Method according to claim 3, in which the conditioning comprises the application of a free-radical generator to the surface of the substrate (1).

5. Method according to claim 1 or 2, in which the conditioning comprises a pulsed O₂/H₂O—H₂/H₂O plasma treatment.

6. Method according to claim 1 or 2, in which the conditioning comprises a pulsed H₂ plasma treatment.

7. Method according to claim 1 or 2, in which the conditioning comprises a pulsed NH₃ plasma treatment.

8. Method according to claim 1 or 2, in which the conditioning comprises production of a thermal nitride, oxynitride, plasma nitride or remote plasma nitride on the surface of the substrate (1).

9. Method according to claim 1 or 2, in which the conditioning comprises production of an oxide on the surface of the substrate (1), the oxide having a composition which contains a desired number of reactive groups with respect to the reactive ligand of the first precursor.

10. Method according to claim 9, in which the conditioning comprises the production of a chemical oxide on the surface of the substrate (1).

11. Method according to claim 10, in which the conditioning comprises the production of a chemical oxide on the surface of the substrate (1) by means of an oxidizing agent, in particular H₂O₂ or O₃, the oxidizing agent preferably being dissolved in D/BHF, HCl, H₂SO₄, NH₄OH, H₂O or a mixture thereof, and the concentration, time and temperature being selected in such a manner that a continuous oxide layer which is as thin as possible is produced.

12. Method according to claim 9, in which the conditioning comprises the production of a chemical oxide on the surface of the substrate (1) by means of one of the following processes:
flushing for 90 seconds with DHF solution (H₂O:HF=100:1), flushing for 5 minutes with HuangA or SC1 (standard clean 1) solution (H₂O₂+NH₃ in H₂O), flushing for 5 minutes in HuangB or SC2 (standard clean 2) solution (H₂O₂+HCl in H₂O);
flushing for 60 s with DHF+Caro's acid;
flushing with HF—H₂O)₂ at 35° C. (50:1);
flushing with HF—H₂O₂ at 45° C. (20:1);
flushing with HF—H₂O₂ at 45° C. (50:1).
